(19) United States
(12) Patent Application Publication
(10) Pub. No.: US 2025/0183041 A1
(43) Pub. Date: Jun. 5, 2025

(54) LOW RESISTANCE MOLYBDENUM DEPOSITION FOR LOGIC SOURCE/DRAIN CONTACTS

(71) Applicant: Lam Research Corporation, Fremont, CA (US)

(72) Inventors: Yao-Tsung HSIEH, San Jose, CA (US); Matthew Bertram Edward GRIFFITHS, Fremont, CA (US); Jeong-Seok NA, San Jose, CA (US); Chiukin Steven LAI, Sunnyvale, CA (US); David Joseph MANDIA, Lake Oswego, OR (US)

(21) Appl. No.: 18/837,560

(22) PCT Filed: Feb. 17, 2023
(86) PCT No.: PCT/US2023/062877

§ 371 Date: Aug. 9, 2024

Related U.S. Application Data
(60) Provisional application No. 63/381,883, filed on Nov. 1, 2022.
(60) Provisional application No. 63/268,484, filed on Feb. 24, 2022.

(51) Int. Cl. H01L 21/285; C23C 16/04; C23C 16/14; H01L 21/311; H10B 12/00; H10D 64/66

(52) U.S. Cl. CPC H01L 21/28562; C23C 16/045; C23C 16/14; H01L 21/28568; H01L 21/31116; H01L 21/31122; H10D 64/665; H10B 12/488

(57) ABSTRACT

Provided is an efficient method for filling a semiconductor substrate conformal layer lined feature utilizing a metal precursor to selectively deposit metal at the bottom of the feature and to etch the conformal layer lining from feature sidewalls.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Deposition of conductive materials is an integral part of many semiconductor fabrication processes. These materials may be used for horizontal interconnects, vias between adjacent metal layers, contacts between metal layers and devices, and as lines in memory devices. In an example of deposition, a tungsten (W) layer may be deposited on a titanium nitride (TiN) barrier layer to form a TiN/W bilayer by a chemical vapor deposition (CVD) process using tungsten (VI) fluoride (WF₆). However, the continued decrease in feature size and film thickness brings various challenges to TiN/W film stacks. These include high resistivity for thinner tungsten films and deterioration of TiN barrier properties.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods of filling features with molybdenum. The features may include a conductive bottom and dielectric sidewalls and may be lined with a conformal liner layer. In some embodiments, the feature including the conformal liner layer is exposed to a molybdenum precursor having dual etch and deposition capabilities. Molybdenum is selectively deposited at the bottom of the feature and conformal layer is etched from feature's sidewalls. In some embodiments, the conformal liner layer is a titanium nitride (TiN) layer. It may be selectively removed without disturbing an underlying layer such as a titanium disilicide (TiSi₂) layer. As a result, an oxygen free, low resistance molybdenum contact to the conductive bottom is formed.

Accordingly, in a first aspect, the present disclosure encompasses a method for filling a feature. In some embodiments, the method includes providing a substrate with a feature having a feature bottom and feature sidewalls in a deposition chamber, the feature having a conformal liner layer. The conformal liner layer lines the feature such that the feature has a lined feature bottom surface and lined feature sidewall surfaces. The method further includes selectively depositing a metal film on the lined feature bottom surface using a metal precursor and a reducing agent to form a metal film base; preferentially etching the conformal liner layer from the feature sidewalls over etching the metal film base with the metal precursor; and using the metal precursor, depositing metal in the feature on the metal film base.

In some embodiments, the reducing agent is hydrogen, hydrazine, ammonia, silane, disilane, diborane, or a combination thereof.

In some embodiments, the conformal liner layer is titanium nitride, titanium silicide nitride, tungsten carbon nitride, or a combination thereof.

In some embodiments, the metal precursor is a molybdenum halide, a molybdenum oxyhalide, or a combination thereof.

In some embodiments, forming the metal film base and etching the conformal liner layer from the sidewalls occur sequentially.

In some embodiments, forming the metal film base and etching the conformal liner layer from the sidewalls occur simultaneously.

In some embodiments, the molybdenum halide is molybdenum dichloride, molybdenum trichloride, molybdenum tetrachloride, molybdenum pentachloride, molybdenum hexachloride, or molybdenum fluoride.

In some embodiments, the molybdenum oxyhalide is molybdenum dichloride dioxide, molybdenum tetrachloride oxide, molybdenum tetrafluoride oxide, or molybdenum dibromide dioxide.

In some embodiments, the temperature of the substrate during deposition is from about 350° C. to about 550° C.

In some embodiments, the pressure in the deposition chamber is from about 10 Torr to about 50 Torr.

In some embodiments, depositing comprises filling the feature with metal.

In some embodiments, the substrate includes a top surface, and the top surface is coated with titanium disilicide.

In some embodiments, the method also includes pre-treating the conformal liner layer to clean it prior to deposition of the metal film.

In some embodiments, preferentially etching is etching the conformal liner layer from the feature sidewalls without etching the metal film base.

In a second aspect, the present disclosure encompasses a method for filling a feature. In some embodiments, the method includes providing a substrate comprising a feature having a feature bottom and feature sidewalls in a deposition chamber, the feature having a conformal liner layer with a lined feature bottom surface and lined feature sidewall surfaces; selectively depositing a molybdenum film on the lined feature bottom surface with a molybdenum precursor and a reducing agent to form a molybdenum film base; preferentially etching the conformal liner layer with the molybdenum precursor to remove the lined feature sidewall surfaces over etching the molybdenum film base; and depositing molybdenum in the feature on the molybdenum film base with the molybdenum precursor.

In some embodiments, preferentially etching is etching the conformal liner layer from the feature sidewalls without etching the metal film base.

In some embodiments, the molybdenum precursor is a molybdenum halide or a molybdenum oxyhalide.

In some embodiments, the molybdenum oxyhalide is molybdenum dichloride dioxide, molybdenum tetrachloride oxide, molybdenum tetrafluoride oxide, or molybdenum dibromide dioxide.

In some embodiments, the molybdenum halide is molybdenum dichloride, molybdenum trichloride, molybdenum tetrachloride, molybdenum pentachloride, molybdenum hexachloride, or molybdenum fluoride.

In some embodiments, the molybdenum halide is molybdenum pentachloride.

In a third aspect, the present disclosure encompasses a method for filling a feature. In some embodiments, the method includes providing a substrate comprising a feature having a feature bottom and feature sidewalls in a deposition chamber, the feature having a conformal liner layer comprising a lined feature bottom surface and lined feature sidewall surfaces; selectively depositing a molybdenum film on the lined feature bottom surface with a first molybdenum precursor and a reducing agent to form a molybdenum film base; preferentially etching the conformal liner layer with a second molybdenum precursor to remove the lined feature sidewall surfaces over etching the molybdenum film base; and depositing molybdenum in the feature on the molybdenum film base with the first molybdenum precursor.

In some embodiments, preferentially etching is etching the conformal liner layer from the feature sidewalls without etching the metal film base.

In a fourth aspect, the present disclosure encompasses an apparatus for filling a feature on a substrate. In some embodiments, the apparatus includes at least one deposition chamber having a pedestal for holding a substrate that has a feature with a feature bottom and feature sidewalls, the feature having a conformal liner layer of a lined feature bottom surface and lined feature sidewall surfaces; at least one inlet port for delivering gas phase metal precursors to the deposition chamber; and a controller for controlling operations in the apparatus, including machine-readable instructions for: causing deposition of a molybdenum film on the lined feature bottom surface with a molybdenum precursor and a reducing agent; preferentially etching the conformal liner layer with the molybdenum precursor to remove the lined feature sidewall surfaces over etching the lined feature bottom surface feature; and after (b) depositing molybdenum in the feature with the molybdenum precursor.

These and other aspects are discussed further below with reference to the drawings.

### BRIEF DESCRIPTION OF DRAWINGS

FIGS. 1A and 1B are schematic examples of material stacks that include molybdenum (Mo) in accordance with certain disclosed embodiments.

FIGS. 2A-2L are schematic examples of various structures into which molybdenum may be deposited in accordance with certain disclosed embodiments.

FIG. 3 is a flow diagram showing certain operations of filling a feature with metal in accordance with certain disclosed embodiments.

FIGS. 4A-4D are schematic diagrams showing cross-sectional depictions of features during fill processes in accordance with certain disclosed embodiments.

FIGS. 5A-5C are schematic diagrams showing cross-sectional depictions of features during fill processes in accordance with certain disclosed embodiments.

FIG. 6 shows an example of an apparatus that may be used to perform the methods described herein in accordance with certain disclosed embodiments.

FIGS. 7A and 7B show examples of apparatuses that may be used to perform the methods described herein in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Definitions

As used herein, the term “about” is understood to account for minor increases and/or decreases beyond a recited value, which changes do not significantly impact the desired function of the parameter beyond the recited value(s). In some cases, “about” encompasses +/−10% of any recited value. As used herein, this term modifies any recited value, range of values or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

As used herein, the phrase “at least one of A, B, and C” should be construed to mean a logical (A or B or C), using a non-exclusive logical OR, and should not be construed to mean ‘at least one of A, at least one of B, and at least one of C.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like. The term “semiconductor substrate” or “substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

It is understood that throughout this specification the identifiers “first” and “second” are used solely to aid in distinguishing the various components and/or steps of the disclosed subject matter. The identifiers “first” and “second” are not intended to imply any particular order, amount, preference or importance to the components and/or steps modified by these terms.

The substrate may be a silicon wafer, e.g., a 200-mm wafer, a 300-mm wafer, or a 450-mm wafer, including wafers having one or more layers of material, such as dielectric, conducting, or semi-conducting material deposited thereon. In various embodiments, the substrate is patterned. A patterned substrate may have “features” such as pillars, poles, trenches, via holes, or contact holes, which may be characterized by one or more of narrow and/or re-entrant openings, constrictions within the feature, and high aspect ratios. The feature(s) may be formed in one or more of the above-described layers. One example of a feature is a pillar or pole in a semiconductor substrate or a layer on the substrate. Another example is a trench in a substrate or layer.

In some embodiments, the feature(s) may have an aspect ratio of at least about 1:1, at least about 2:1, at least about 4:1, at least about 6:1, at least about 10:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a negative feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature.

Provided herein are methods of filling features with molybdenum (Mo) that may be used for logic applications. Mo offers several benefits over other metals such as cobalt (Co), ruthenium (Ru), and tungsten (W): (i) barrier-less and liner-less Mo film deposition is more feasible on oxide and nitride as compared to Co, Ru, and W, (ii) Mo resistivity scaling is better than W, and (iii) there is relatively easy Mo integration into current W schemes compared to Co and Ru.

Provided herein are methods of deposition Mo on source/drain (S/D) features that prevent damaging an underlying silicide (e.g., titanium silicide or TiSiₓ) layer. While the description below focuses on Mo deposition for source/drain contact, aspects of the methods may also be used for other metallization schemes in logic and/or memory applications.

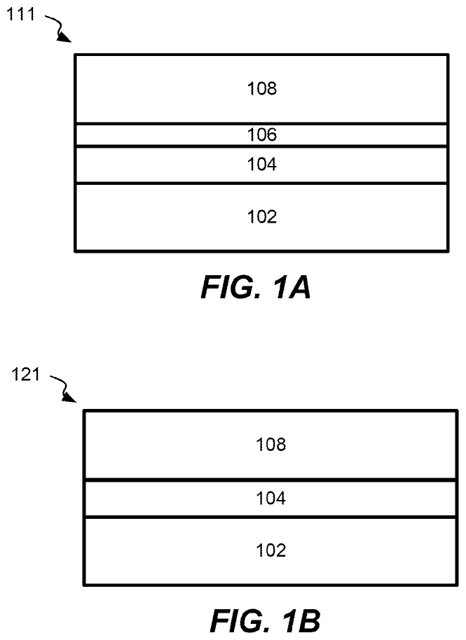

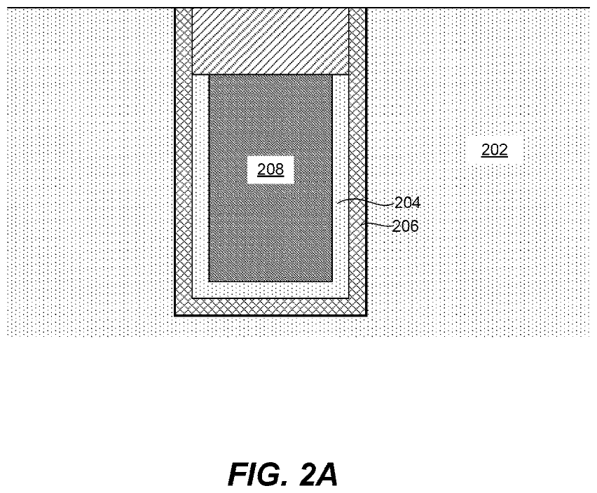

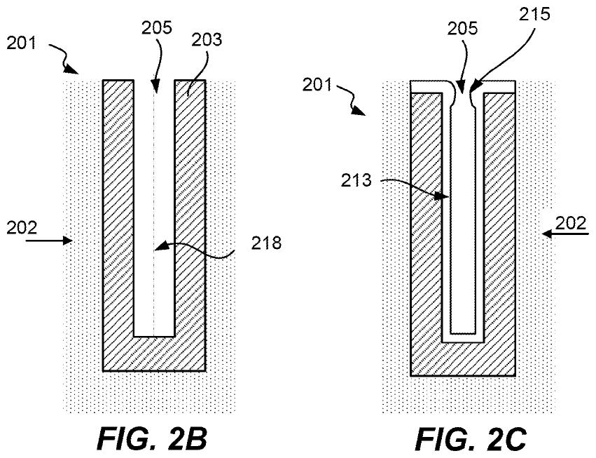

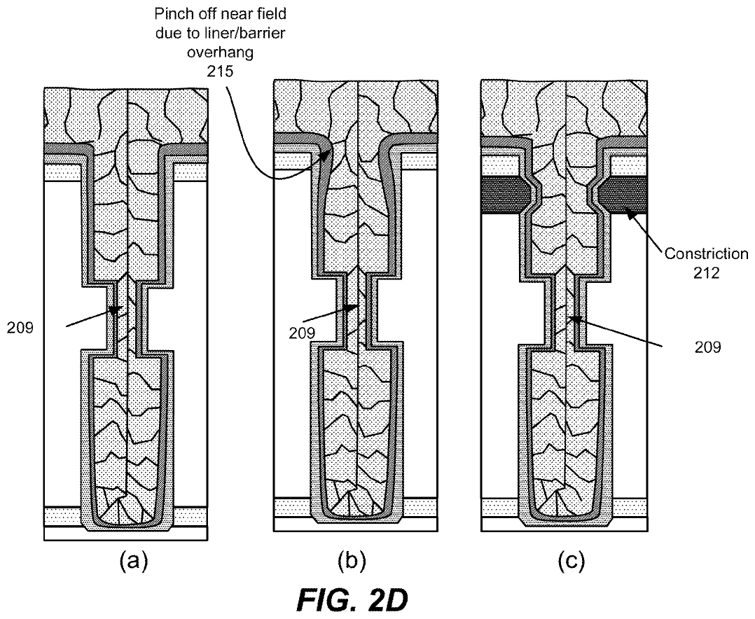

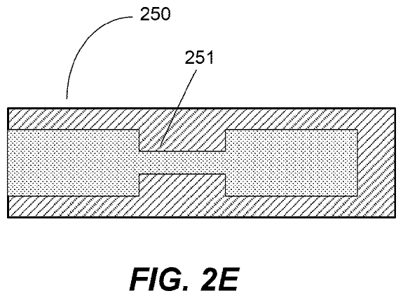

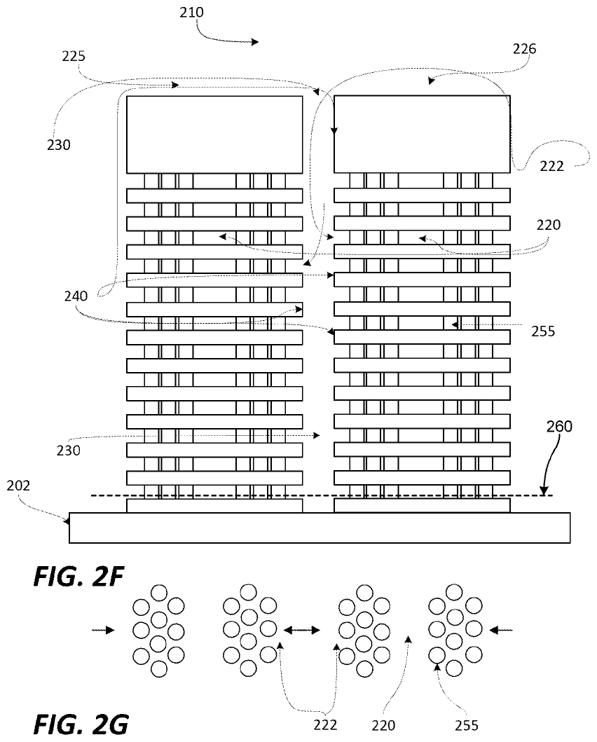

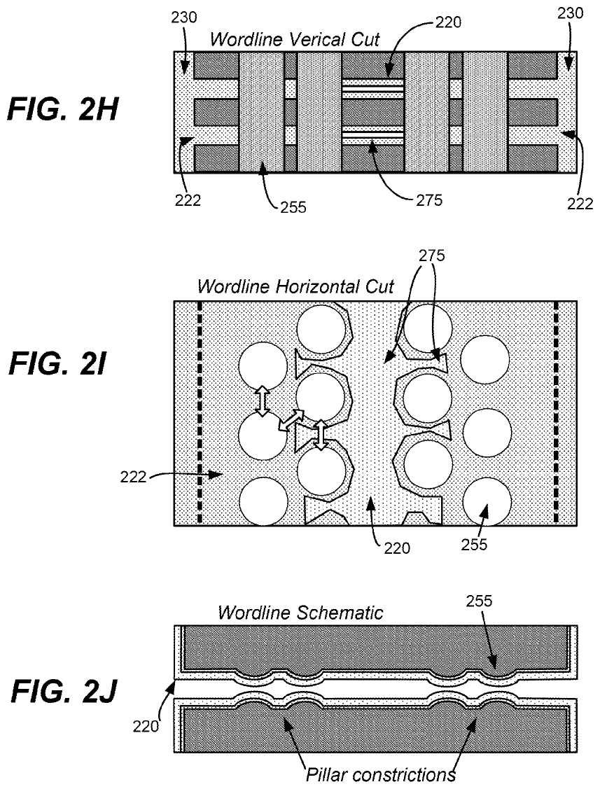

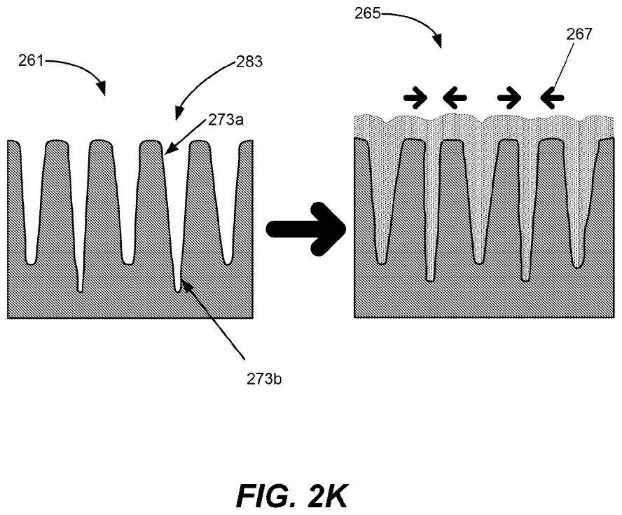

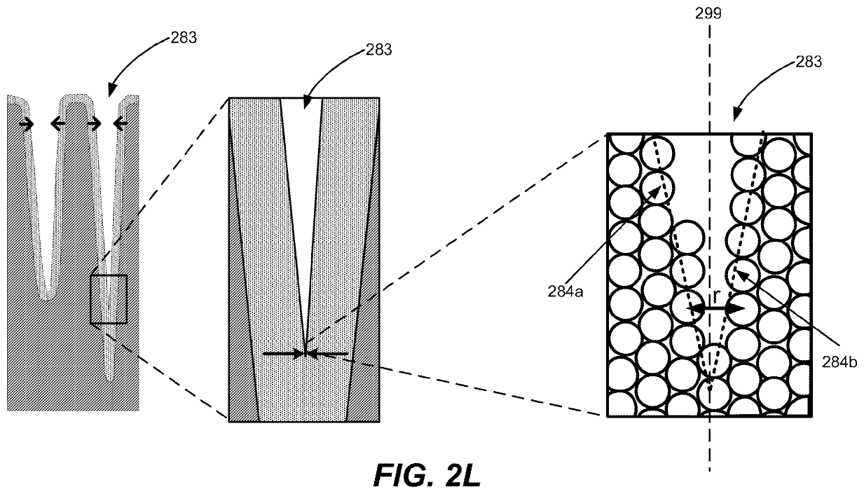

FIGS. 1A and 1B are schematic examples of material stacks that include Mo according to various embodiments. FIGS. 1A and 1B illustrate the order of materials in examples of particular stacks and may be used with any appropriate architecture and application, as described further below with respect to FIGS. 2A-2L. FIG. 1A shows a first material stack 111 featuring a substrate 102 and a Mo layer 108 deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. In some embodiments, the substrate 102 may be or include silicon (Si) or silicon germanium (SiGe). The methods may also be applied to form metallization stack structures on other substrates, such as glass, plastic, and the like.

The stack 111 has a dielectric layer 104 on the substrate 102. The dielectric layer 104 may be deposited directly on a semiconductor surface (e.g., a Si or SiGe surface) of the substrate 102, or there may be any number of intervening layers. For example, the substrate 102 may include any number of layers deposited in various arrangements on a semiconductor surface.

Examples of dielectric layers include doped and undoped silicon oxide, silicon nitride, and aluminum oxide layers, with specific examples including doped or undoped layers of SiO₂ and Al₂O₃. The stack 111 has a layer 106 disposed between the Mo layer 108 and the dielectric layer 104. The layer 106 may be a diffusion barrier and/or an adhesion layer, for example. A diffusion barrier is a layer that prevents diffusion of species between layers. An adhesion layer is a layer that promotes adhesion of a layer to an underlying layer. Examples of diffusion barrier and adhesion layers include titanium nitride (TiN), titanium/titanium nitride (Ti/TiN), tungsten (W), tungsten nitride (WN), and tungsten carbon nitride (WCN). The Mo layer 108 is the main conductor of the structure. In some embodiments, the Mo layer 108 may include multiple bulk layers deposited at different conditions. The Mo layer 108 may or may not include a Mo nucleation layer. Further, in some embodiments, the Mo layer 108 may be deposited on a growth initiation layer that includes another material, such as a tungsten (W) or W-containing growth initiation layer.

FIG. 1B shows another example of a material stack 121. In this example, the stack 121 includes the substrate 102, dielectric layer 104, with Mo layer 108 deposited directly on the dielectric layer 104, without an intervening diffusion barrier or adhesion layer. The Mo layer 108 is as described with respect to FIG. 1A. By using Mo as the main conductor (which has a lower electron mean free path than W) lower resistivity thin films can be obtained.

In some embodiments, a stack (not shown) may include the substrate, a nitride, silicide, or metal layer, and a Mo layer deposited onto the nitride, silicide, or metal layer. In these embodiments, there is no dielectric layer between the Mo layer and the nitride, silicide, or metal layer. Examples include Mo on a metal nitride layer (e.g., TiN, WN, WCN, or MoN), Mo on a metal silicide layer (e.g., TiSiₓ, or tungsten silicide (WSiₓ), or on a metal layer (e.g., W). In still some other embodiments of a stack (not shown), the stack may include a substrate and a Mo layer deposited directly on the substrate, including directly on a semiconducting surface, on a dielectric surface, or on a conductive surface. FIGS. 1A and 1B illustrate examples of order of materials in a particular stack and may be used with any appropriate architecture and application, as described further below with respect to FIGS. 2A-2L.

The methods described herein are performed on a substrate that may be housed in a chamber. The substrate may be a silicon or other semiconductor wafer, including wafers having one or more layers of material, such as dielectric, conducting, or semi-conducting material deposited thereon. The methods are not limit to semiconductor substrates and may be performed to fill any feature with molybdenum.

Substrates may have features such as vias or contact holes, which may be characterized by one or more of narrow and/or re-entrant openings, constrictions within the feature, and high aspect ratios. A feature may be formed in one or more of the above-described stacks or layers within a stack. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

FIG. 2A depicts a schematic example of a Dynamic Random-Access Memory (DRAM) architecture including a Mo buried wordline (bWL) 208 in a silicon substrate 202. The Mo bWL is formed in a trench etched in the silicon substrate 202. Lining the trench is a conformal barrier layer 206 and an insulating layer 204. The conformal barrier 206 is disposed between the insulating layer 204 and the silicon substrate 202. In this example, the insulating layer 204 may be a gate oxide layer, formed from a high-k dielectric material such as a silicon oxide or silicon nitride material. In some embodiments disclosed herein the conformal barrier layer 206 is TiN or a tungsten-containing layer. In embodiments in which TiN is used as a conformal barrier layer, a conformal tungsten-containing growth initiation layer (not shown) may be present between the conformal barrier layer 206 and the Mo bWL 208. Alternatively, the Mo bWL 208 may be deposited directly on a TiN or other diffusion barrier. In some embodiments, one or both of layers 204 and 206 is not present.

The bWL structure shown in FIG. 2A is one example of an architecture that includes a Mo fill layer. During fabrication of the bWL, Mo is deposited into a feature that may be defined by an etched recess in the silicon substrate 202 that is conformally lined with layers 206 and 204, if present.

FIGS. 2B-2H are additional schematic examples of various structures into which Mo may be deposited in accordance with disclosed embodiments. FIG. 2B shows an example of a cross-sectional depiction of a vertical feature 201 to be filled with Mo. The feature can include a feature hole 205 in a substrate 202. The feature hole 205 may have a conformal liner layer 203 lining the sidewall or interior of the feature hole 205 and may form the interior surfaces. The hole 205 or other feature may have a dimension near the opening, e.g., an opening diameter or line width of between about 10 nm to 500 nm, for example between about 25 nm and about 300 nm. The feature hole 205 can be referred to as an unfilled feature or simply a feature. The feature 201, and any feature, may be characterized in part by an axis 218 that extends through the length of the feature, with vertically oriented features having vertical axes and horizontally-oriented features having horizontal axes.

In some embodiments, features are wordline features in a 3D NAND structure. For example, a substrate may include a wordline structure having an arbitrary number of wordlines (e.g., 50 to 150) with vertical channels at least 200 Å deep. Examples of wordline features are described further below. Another example of a feature is a trench in a substrate or layer. Features may be of any depth. In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

FIG. 2C shows an example of a feature 201 that has a re-entrant profile. A re-entrant profile is a profile that narrows from a bottom, closed end, or interior of the feature to the feature opening. According to various implementations, the profile may narrow gradually and/or include an overhang at the feature opening. FIG. 2C shows an example of the latter, with a conformal liner layer 213 lining the sidewall and bottom surfaces of the feature hole 105. The conformal liner layer 213 can be a diffusion barrier layer, an adhesion layer, a nucleation layer, a combination of thereof, or any other applicable material. Non-limiting examples of liner layers can include dielectric layers and conducting layers. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC); and low k dielectrics, such as carbon-doped SiO₂. In certain implementations, a liner layer can be one or more of titanium, titanium nitride, tungsten nitride, titanium aluminide, tungsten, and molybdenum.

The conformal liner layer 213 forms an overhang 215 such that the conformal liner layer 213 is thicker near the opening of the feature 201 than inside the feature 201.

In some implementations, features having one or more constrictions within the feature may be filled. FIG. 2D shows examples of views of various filled features having constrictions. Each of the examples (a), (b) and (c) in FIG. 2D includes a constriction 209 at a midpoint within the feature. The constriction 209 can be, for example, between about 15 nm-20 nm wide. Constrictions can cause pinch off during deposition molybdenum in the feature using conventional techniques, with deposited metal blocking further deposition past the constriction before that portion of the feature is filled, resulting in voids in the feature. Example (b) further includes a liner/barrier overhang 215 at the feature opening. Such an overhang could also be a potential pinch-off point. Example (c) includes a constriction 212 further away from the field region than the overhang 215 in example (b).

Horizontal features, such as in 3-D memory structures, can also be filled. FIG. 2E shows an example of a horizontal feature 250 that includes a constriction 251. For example, horizontal feature 250 may be a word line in a 3D NAND (also referred to as vertical NAND or VNAND) structure. In some implementations, the constrictions can be due to the presence of pillars in a 3D NAND or other structure. FIG. 2F presents a cross-sectional side-view of a 3-D NAND structure 210 (formed on a silicon substrate 202) having VNAND stacks (left 225 and right 226), central vertical structure 230, and a plurality of stacked horizontal features 220 with openings 222 on opposite sidewalls 240 of central vertical structure 230. Note that FIG. 2F displays two “stacks” of the exhibited 3-D NAND structure 210, which together form the “trench-like” central vertical structure 230, however, in certain embodiments, there may be more than two “stacks” arranged in sequence and running spatially parallel to one another, the gap between each adjacent pair of “stacks” forming a central vertical structure 230, like that explicitly illustrated in FIG. 2F. In this embodiment, the horizontal features 220 are 3-D memory wordline features that are fluidically accessible from the central vertical structure 230 through the openings 222. The presence of pillars 255 can create constrictions in the horizontal features 220, as shown more clearly in FIG. 2G, discussed below. Although not explicitly indicated in the figure, the horizontal features 220 present in both the 3-D NAND stacks 225 and 226 shown in FIG. 2F (i.e., the left 3-D NAND stack 225 and the right 3-D NAND stack 226) are also accessible from the other sides of the stacks (far left and far right, respectively) through similar vertical structures formed by additional 3-D NAND stacks (to the far left and far right, but not shown). Each 3-D NAND stack 225, 226 contains a stack of wordline features that are fluidically accessible from both sides of the 3-D NAND stack through a central vertical structure 230. In the particular example schematically illustrated in FIG. 2F, each 3-D NAND stack contains 6 pairs of stacked wordlines. However, a 3-D NAND memory layout may contain any number of vertically stacked pairs of wordlines.

The wordline features in a 3-D NAND stack can be formed by depositing an alternating stack of silicon oxide and silicon nitride layers, and then selectively removing the nitride layers leaving a stack of oxides layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a VNAND stack may include between 2 and 512 horizontal wordline features, between 2 and 256 horizontal wordline features, or between 8 and 128 horizontal wordline features, or between 16 and 64 horizontal wordline features, and so forth (the listed ranges understood to include the recited end points).

FIG. 2G presents a cross-sectional top-down view of the same 3-D NAND structure 210 shown in side-view in FIG. 2F with the cross-section taken through the horizontal section 260 as indicated by the dashed horizontal line in FIG. 2F. The cross-section of FIG. 2G illustrates several rows of pillars 255, which are shown in FIG. 2F to run vertically from the base of semiconductor substrate 202 to the top of 3-D NAND stack 210. In some embodiments, the pillars 255 are formed from a polysilicon material and are structurally and functionally significant to the 3-D NAND structure 210. In some embodiments, such polysilicon pillars may serve as gate electrodes for stacked memory cells formed within the pillars. The top-view of FIG. 2G illustrates that the pillars 255 form constrictions in the openings 222 to wordline features 220. Fluidic accessibility of wordline features 220 from the central vertical structure 230 via openings 222 (as indicated by the arrows in FIG. 2G) is inhibited by pillars 255. In some embodiments, the size of the horizontal gap between adjacent polysilicon pillars is between about 1 and 20 nm. This reduction in fluidic accessibility increases the difficulty of uniformly filling wordline features 220 with material. The structure of wordline features 220 and the challenge of uniformly filling them with molybdenum material due to the presence of pillars 255 is further illustrated in FIGS. 2H, 2I, and 2J.

FIG. 2H exhibits a vertical cut through a 3-D NAND structure similar to that shown in FIG. 2F, but here focused on a single pair of wordline features 220 and additionally schematically illustrating a fill process which resulted in the formation of a void 275 in the filled wordline features 220. FIG. 2I also schematically illustrates void 275, but in this figure illustrated via a horizontal cut through pillars 255, similar to the horizontal cut exhibited in FIG. 2G. FIG. 2J illustrates the accumulation of molybdenum material around the constriction-forming pillars 255, the accumulation resulting in the pinch-off of openings 222, so that no additional molybdenum material can be deposited in the region of voids 275. Apparent from FIGS. 2H and 2I is that void-free molybdenum fill relies on migration of sufficient quantities of deposition precursor down through vertical structure 230, through openings 222, past the constricting pillars 255, and into the furthest reaches of wordline features 220, prior to the accumulated deposition of molybdenum around pillars 255 causing a pinch-off of the openings 222 and preventing further precursor migration into wordline features 220. Similarly, FIG. 2J exhibits a single wordline feature 220 viewed cross-sectionally from above and illustrates how a generally conformal deposition of molybdenum material begins to pinch-off the interior of wordline feature 220 due to the fact that the significant width of pillars 255 acts to partially block, and/or narrow, and/or constrict what would otherwise be an open path through wordline feature 220. (It should be noted that the example in FIG. 2J can be understood as a 2-D rendering of the 3-D features of the structure of the pillar constrictions shown in FIG. 2I, thus illustrating constrictions that would be seen in a plan view rather than in a cross-sectional view.)

Three-dimensional structures may need longer and/or more concentrated exposure to precursors to allow the innermost and bottommost areas to be filled. Three-dimensional structures can be particularly challenging when employing molybdenum halide and/or molybdenum oxyhalide precursors because of their proclivity to etch, with longer and more concentrated exposure allowing for more etch as parts of the structure.

FIGS. 2K and 2L show examples of an asymmetric trench structure DRAM bWL. Some fill processes for DRAM bWL trenches can distort the trenches such that the final trench width and resistance Rs are significantly non-uniform. FIG. 2K shows an unfilled 261 and filled 265 narrow asymmetric trench structure DRAM bWL that exhibit line bending after fill. As shown, multiple features 283 are depicted on a substrate. These features 283 are spaced apart, and in some embodiments, adjacent features have a pitch between about 20 nm and about 60 nm or between about 20 nm and 40 nm. The pitch is defined as the distance between the middle axis of one feature to the middle axis of an adjacent feature. The unfilled features 283 may be generally V-shaped as shown in feature 283, having sloped sidewalls where the width of the feature narrows from the top of the feature to the bottom of the feature. The features widen from the feature bottom 273b to the feature top 273a. After some fill operations, line bending may be observed within the feature 283, as shown in substrate 265. Without being bound by a particular theory, it is believed that a cohesive force between opposing surfaces of a trench pulls the trench sides together as depicted by arrows 267. This phenomenon is illustrated in FIG. 2L and may be characterized as “zipping up” the feature. As the feature 283 is filled, more force is exerted from a center axis 299 of the feature 283, causing line bending. For example, molybdenum may be deposited on the sidewalls of the feature 283. Deposited molybdenum 284a and 284b on sidewalls of feature 283 thereby interact in close proximity, where molybdenum-molybdenum bond radius r is small, thereby causing cohesive interatomic forces between the smooth growing surfaces of tungsten and pulling the sidewalls together, thereby causing line bending. Described below are methods of filling features to reduce line bending.

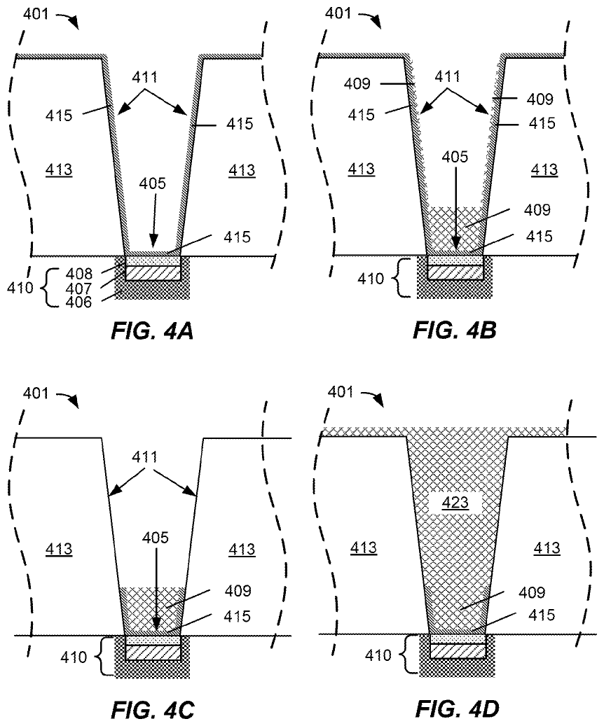

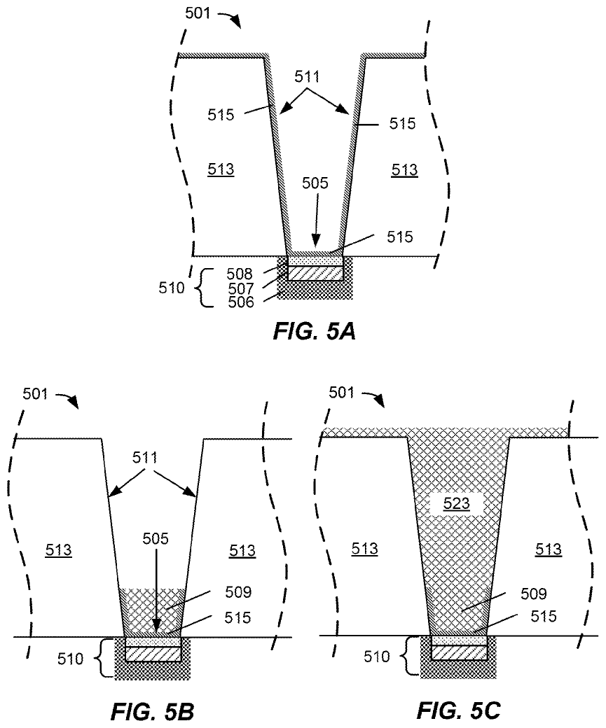

Provided below are methods of filling features with Mo. The methods described herein include deposition, etch, and clean operations which may be used to fill substrate features such as those described above. Further examples of features are described below with respect to FIGS. 4A-4D and 5A-5C.

Examples of feature fill for horizontally-oriented and vertically-oriented features are described below. It should be noted that in at least most cases, the examples are applicable to both horizontally-oriented or vertically-oriented features. Horizontally-oriented features generally refers to features oriented such that the feature axis is parallel to the plane of the substrate surface. Vertically-oriented features generally refers to features oriented such that the feature axis is orthogonal to the plane of the substrate surface.

Deposition of molybdenum as described herein involves reacting a Mo-containing precursor, also referred to as a Mo precursor. In some embodiments, a Mo precursor is a molybdenum chloride (MoClₓ) compound also referred to as a molybdenum chloride precursor or MoClₓ precursor. Molybdenum chloride precursors are given by the formula MoClₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ precursors, in other embodiments, other molybdenum halide precursors may be used. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

In some embodiments, the feature may be fill using a molybdenum oxyhalide precursor. Molybdenum oxyhalide precursors are given by the formula MoO_{y}X_{z}, where X is a halogen (fluorine (F), chlorine (Cl), bromine (Br), or iodine (I)) and y and z are numbers greater than 0 such that MoO_{y}X_{z} forms a stable compound. Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum oxy-iodides MoO₂I, MoO₂F₂, MoO₂I₂, MoOBr₄, MoOI₄ and Mo₄O₁₁I. A feature may be filled with Mo using a MoClₓ precursor, MoO_{y}X_{z} precursor, or a combination thereof.

In some embodiments, selectively depositing molybdenum on a metal-containing bottom includes exposing a feature to a molybdenum oxyhalide. In some embodiments, the treatment inhibits molybdenum growth on oxide or nitride sidewalls. In some embodiments, the treatment is performed without depositing molybdenum in the feature. In some embodiments, the treatment further includes exposing the feature to a co-reactant capable of reducing the molybdenum halide to form molybdenum.

In certain embodiments, the precursor is a combination of a molybdenum halide (MoX_{z}) as described above and a molybdenum oxyhalide precursor (MoO_{y}X_{z}) as described above.

For deposition of Mo into the feature, the Mo precursor may be reacted with a co-reactant. Examples of co-reactants include hydrogen (H₂), silane (SiH₄), diborane (B₂H₆), germane (GeH₄), ammonia (NH₃), and hydrazine (N₂H₄).

In some embodiments, deposition of Mo may use a plasma-based process. Gas may be fed into a remote or in-situ plasma generator to generate plasma species. Examples of gas which may be used to generate plasma may be a hydrogen-containing gas, such as H₂ or nitrogen-containing gas, such as N₂. The plasma species may be inert or react with the Mo precursor to form a film.

A feature may be filled with Mo by atomic layer deposition (ALD) or chemical vapor deposition (CVD). Thermal ALD or plasma enhanced ALD (PEALD) may be used. Similarly, thermal CVD or plasma enhanced CVD (PECVD) may be used.

ALD is a surface-mediated deposition technique in which doses of a precursor and a reactant are sequentially introduced into a deposition chamber. One or more cycles of sequentially doses of a Mo precursor and reactant may be used to deposit Mo. For example, in the deposition of an initial Mo layer, MoCl₅ may be used as a precursor and H₂ as a reducing agent. The reducing agent is also referred to as a co-reagent. The pulsing sequence is generally: 1) introduce reducing agent; 2) optional Ar purge; 3) introduce molydenum-containing precursor; and 4) optional Ar purge.

For example, doses of MoCl₅ and H₂ may be sequentially introduced into the deposition chamber with a purge gas, such as argon, flowed between. For ALD, the temperature of the substrate and the pressure of the chamber may be controlled. For example, the substrate may be heated between 500° C. and 800° C., e.g., between 650° C. and 750° C. In some embodiments, the chamber may be pressurized to at least 10 Torr, e.g. at least 30 Torr. In some embodiments, the temperature and/or pressure may be used to control the rate of reactions. In some embodiments, the temperature and/or pressure may be used to control selectivity.

In some embodiments, Mo fill may involve CVD. In a CVD process, the Mo precursor and reactant are in vapor phase together in the deposition chamber. Generally speaking, a CVD process fills a feature faster than an ALD process. In one example, the precursor may be a molybdenum chloride, such as MoCl₅, and is flowed into the chamber with a reactant, such as H₂. In this example, the wafer is simultaneously exposed to the precursor and reactant which react and fill features with Mo.

In still some other embodiments, a feature may be filled using pulsed CVD process. The pulsed CVD process continuously flows a reactant into a chamber while pulses of a precursor are flowed into the chamber. For example, H₂ gas may be flowed into the chamber and is continuously flowed into the chamber while MoCl₅ is intermittently flowed into the chamber. Temperature of the substrate and pressure in the chamber may be controlled during a CVD operation.

Mo may be selectively deposited into a feature using the methods described herein. In selective deposition, Mo fill may be deposited easier on a first material with respect to a second material, e.g., Mo deposition and growth may be easier on a metal material relative to Mo deposition and growth on a dielectric material. For example, a feature may have a sidewall surface of SiO₂ and a TiN plug in a bottom portion of the feature. In selective deposition, Mo is deposited into the feature and may grow on the TiN plug but not grow (or grow to a lesser extent) on the SiO₂ sidewall surfaces. In this example, by having the Mo grow from the bottom of the feature on the TiN plug and not the sidewall surfaces, the feature avoids the line bending effect described above in FIG. 2L.

Process conditions such as the precursor gas, the reducing agent, substrate temperature, process pressure, and exposure time may affect the selectivity of the Mo film being deposited. Different precursor gases may have different process windows in which Mo film may be selectively deposited. For example, MoCl₅ has a higher selectivity than MoO₂Cl₂, i.e., under the same temperature and pressure conditions, the precursor gas of MoCl₅ may deposit Mo only on a conductive surface and not on a dielectric surface while a precursor gas of MoO₂Cl₂ may deposit Mo on both conductive and dielectric surfaces. Generally speaking, MoCl₅ gas has a large process window, i.e., large temperature and pressure range, where the precursor gas retains its selectivity. For example, MoCl₅ may be selectively deposited on a metal material with respect to a dielectric material where the process temperature is 300° C. to 800° C. In some embodiments, the substrate temperature is 350° C. to 550° C. Generally speaking, higher process temperatures and higher process pressures reduce the selectivity of the deposited gas. For example, at higher temperatures, a precursor gas such as MoCl₅ may lose its selectivity and deposit Mo film on both a metal surface and dielectric surface within a feature.

Described below are examples of deposition of Mo film within a feature using a MoCl₅ precursor and different process controls. In a first example, the MoCl₅ precursor is reacted with hydrogen (H₂) reducing agent using the deposition methods described above. Process temperatures for selective deposition of the Mo film may be between 400° C. to 800° C. At these temperatures, the Mo film is selectively deposited on conductive metal or metal compound surfaces, such as a TiN surface, in a feature relative to dielectric surfaces. The Mo film grows from the locations where the conductive surfaces are located in a feature. If the conductive surface is a TiN plug at the bottom of the feature, the Mo film may be deposited and grown from the bottom of the feature. In a second example, the Mo film may be deposited using the MoCl₅ precursor and the H₂ reactant, but at higher temperatures, i.e., above 800° C. This process window may have the Mo film deposited on both the dielectric and conductive surfaces within the feature.

A MoClₓ precursor may be used for both deposition and etch operations. For example, in certain process windows, a MoCl₅ precursor may concurrently grow a Mo film and etch away a metal or metal compound film in the feature. The process is considered an etch operation if the rate of material removed is greater than the material deposited by the precursor. The speed at which the precursor deposits material and etches material may be controlled by a variety of process conditions, including the type of reactant used and the process temperature. Generally speaking, the lower the temperature, the higher the ratio of etching away material is relative to deposition of material. At higher temperatures, the same precursor and reactant may be used as a deposition operation, i.e., the amount of material deposited is greater than the material removed. For example, MoCl₅ precursor and H₂ reactant may be used in an etch operation when the process temperature is below 400° C. The same precursor of MoCl₅ and H₂ reactant may be used in a deposition operation when the process temperature is above 550° C. In some embodiments, etching is performed by supplying MoCl₅ or other MoClₓ precursor without a co-reactant. And, as described further below, net etching and/or deposition is controllably varied throughout a feature by implementing a concentration gradient of precursor in a feature. In some embodiments, MoClₓ precursors are used for oxygen-free, fluoride-free deposition. However, other molybdenum halides and molybdenum oxyhalides may be used as described herein for etch and deposition.

A feature may have surface oxide or contaminants on it. For example, the surface of an underlying TiN, WCN, WN, or W layer may be oxidized. If incorporated into the device, the oxidized surface can result in higher resistivity. Clean operations are used to remove such oxides and contaminants. In some embodiments, the clean operation may have the feature soaked in a Mo precursor gas, typically a Mo halide. Similar to the etch operations described above, the precursor gas may be a MoClₓ precursor. In some embodiments, the soak may be done continuously. In some embodiments, the soak may be pulsed, cycling MoClₓ and a purge gas, such as argon (Ar). The precursor may be a non-oxygen Cl-containing Mo compound able to remove oxidation from the feature's surfaces. Examples of MoClₓ compounds are given above. A Cl-containing precursor may be used where traditional cleaning with thermal or plasma H₂ does not work, such as where the oxidized surface is stable on the surface material. A Cl-containing precursor is less likely to over-etch a feature's liner layer or attack a feature's surfaces than a F-containing compound.

In some embodiments, the methods described herein involve deposition of Mo on a protective layer. For example, a nitride layer such as TiN may be used in source/drain contact schemes to protect oxidation of an underlying silicide (e.g., TiSiₓ). In some embodiments, the methods described herein involve liner-free fill of features. For example, a feature may be provided with a conformal liner layer, which serves as a protective layer for an underlying silicide or other layer. In some embodiments, the methods involve removing the part of the conformal liner layer while allowing the portion that protects the underlying layer to remain. Removing the liner lowers the resistance of the contact or other filled feature.

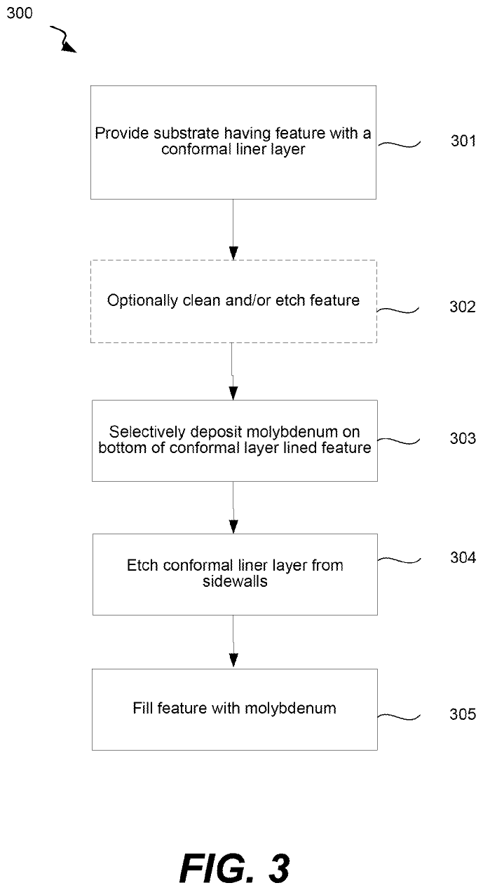

FIG. 3 is a process flow diagram illustrating a method to fill a feature having a conformal liner layer with a Mo film. While FIG. 3 describes deposition of Mo, in other embodiments the method may be used to deposit vanadium, niobium, tantalum, chromium, tungsten, iron, ruthenium, rhenium, rhodium, aluminum, iridium, nickel, zinc, or copper by using the appropriate metal precursor. In some embodiments, the feature has a conformal liner layer. Examples of conformal liner layers include metal oxides and metal nitrides. In some embodiments, the conformal liner layer is a protective nitride layer. Method 300 begins with providing a substrate including a feature with a conformal liner layer in an operation 301. The substrate may be provided to a semiconductor processing tool. In some embodiments, the conformal liner layer is a metal nitride layer, which may be a titanium nitride (TiN) layer. Deposition of a metal such as molybdenum on a TiN liner may cause seam voids and high contact resistance in a full film stack. A liner-free contact may have decreased resistance.

In some embodiments, the metal nitride layer may be a tungsten carbide nitride (WCN) layer. Other nitrides and carbonitrides may be employed. In some embodiments, the layer may be an oxynitride, an oxycarbide, or an oxycarbonitride. The methods are not limited to particular protective layers but may be performed with any protective layer. Still further, the methods may be performed to deposit a metal in a feature without a protective layer in some embodiments.

In some embodiments, the feature is formed in a dielectric material. Mo may be deposited in the feature to make electrical contact to an underlying layer. Examples of underlying layers include metals, metal silicides, and semiconductors. Examples of metals include Co, Ru, copper (Cu), W, Mo, nickel (Ni), iridium (Ir), rhodium (Rh), tantalum (Ta), and Ti. Examples of metal silicides include TiSiₓ, nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ). Examples of semiconductors include silicon (Si), silicon germanium (SiGe), and gallium arsenide (GaAs) with or without semiconductor dopants such as carbon (C), arsenic (As), boron (B), phosphorus (P), tin (Sn), and antimony (Sb).

The feature generally has sidewalls with sidewall surfaces and a bottom with a bottom surface. The sidewalls may be made of one or more layers. The sidewall extends from the field to the bottom. The feature bottom may extend from a first sidewall in the feature to a second sidewall in the feature and may be made of one or more layers. The sidewall surface is the exposed area on the sidewall and may change during wafer processing, e.g., the sidewall surface may change from a first material to a second material after the second material is deposited onto the sidewall. Similarly, the bottom surface is the exposed area on the bottom and may change during wafer processing. In some embodiments, the sidewall surfaces may be the same material as the bottom surface. For example, in some embodiments, the sidewall surfaces and the bottom surface are TiN. In some embodiments, the sidewall surfaces may be a different material than the material of the bottom surface.

In some embodiments, a conformal metal nitride layer forms the sidewall surfaces and bottom surface. For example, a TiN liner layer may line the unfilled feature and form the sidewall surfaces and bottom surface.

In some embodiments, the feature surfaces as provided in operation 301 are oxidized. Oxidation may be caused by exposing a feature's surfaces to air or other oxidizing conditions. For example, a TiN liner surface may be oxidized to be oxidized titanium nitride layer (TiOₓN_{y}) on exposure to air. Other examples of oxidized surfaces include oxidized metal nitrides (MNₓO_{y}), oxidized silicon (SiOₓ), and oxidized silicon-germanium (SiGeOₓ). (In the description herein, the subscripts x and y are used in formulas to denote non-zero numbers. Lack of a subscript does not imply a particular ratio of elements in a compound.)

In some embodiments, oxidizing conditions occur in the course of substrate processing or transfer operations. In some embodiments, an intentional oxidation is performed.

After providing a substrate including a feature having a metal nitride layer or other conformal liner layer and in which Mo is to be deposited, an optional clean may be performed in operation 302. The optional clean may be used to remove oxide on the feature's surfaces. In some embodiments, a hydrogen plasma treatment, a thermal hydrogen treatment, or a reducing treatment, may be used to reduce oxidized metal on a metal substrate at the feature bottom. In some embodiments, an atomic layer clean with a chlorine-based plasma, a hydrogen fluoride (HF) vapor clean, an ammonium fluoride (NH₄F) clean, or a treatment using other reducing agents may be used to reduce oxide off a feature surface.

In some embodiments the clean may use a molybdenum halide, such as MoCl₅. In embodiments in which exposure to a molybdenum halide is used to remove the oxide, the conditions and/or dosing is such that the metal nitride is not etched. The feature may be exposed to a continuous or pulsed flow of the molybdenum halide. While an inert gas such as argon (Ar) may be present, a co-reactant such as hydrogen (H₂) is generally not present to prevent deposition. Exposure to a molybdenum halide may be performed in the same chamber as subsequent fill operations.

A metal such as molybdenum may be selectively deposited in the feature bottom in an operation 303 to form a metal film base such as a molybdenum film base. As used herein, the phrases “metal film base” and “molybdenum film base” refer to a metal film (such as a molybdenum film) deposited at the bottom of a feature that serves as a foundation layer for subsequently formed metal or metal films. The Mo film base is deposited by introducing a Mo precursor and a reducing agent into the deposition chamber. In some embodiments, the reducing agent is continuously flowed while the Mo precursor is pulsed. In some embodiments, both the reducing agent and the Mo precursor are pulsed in alternating sequence. Etching and deposition are controlled to deposit Mo selectively at the bottom of the feature with deposition on the sidewalls and field region not present (due to net etch) or present to a much lesser degree (due to more etch in these areas than at the feature bottom).

A MoClₓ precursor, such as MoCl₅, is used in some embodiments. As discussed above, other MoX_{z} precursors may be used in other embodiments. Examples of reducing agents used are discussed above. A non-oxygen-containing Mo precursor prevents oxidation of the feature's surfaces. It also prevents oxygen from being incorporated into the initial Mo layer. Oxidation increases contact resistance. The lack of oxidation and oxygen incorporation ensures the contact resistance remains low. In some embodiments, an oxyhalide precursor, such as MoOCl₄ may be used. However, the oxyhalide may introduce oxidation into the feature's surfaces and can increase contact resistance.

In some embodiments, operation 303 involves operating in a mass transport limited regime. Because MoCl₅ or other molybdenum halides can etch as well as react to deposit molybdenum, a concentration gradient of molybdenum precursor within the feature can be used to have net deposition at the feature bottom and net etch or substantially less deposition closer to the feature opening. Mass transport limiting conditions of the molybdenum precursor within a feature may be used to achieve this.

Mass transport limiting conditions may be characterized, in part, by concentration gradient of the reactant(s) in the feature. In certain embodiments, reactant concentration is lower further inside the feature than near its opening, resulting in a higher etching rate near the opening than further inside. This in turn can lead to net deposition at the bottom of the feature and no or substantially less deposition closer to the feature opening. Mass transport limiting process conditions may be achieved by supplying limited amounts of reactant into the processing chamber (e.g., use low etchant flow rates relative to the cavity profile and dimensions), while maintaining relative high etching rates in order to consume some etchant as it diffuses into the feature. In certain embodiments, a concentration gradient is substantial, which may be caused relatively high etching kinetics and relative low etchant supply. In certain embodiments, an etching rate near the opening may also be mass transport limited. To achieve a mass transport limited regime, relative amounts and/or concentrations of the molybdenum precursor and reducing agent may be controlled, along with chamber pressure. Temperature may also be controlled to control the reaction rate.

During the deposition, the temperature of the substrate and the pressure of a chamber may be controlled. In some embodiments, the substrate may be heated between 350° C. and 550° C., e.g., between 400° C. and 500° C. In some embodiments, the chamber may be pressurized to at least 10 Torr, e.g., to at least 30 Torr, or to at least 50 Torr. In some embodiments, process parameters such as temperature and pressure, may be used to control selectivity.

Feature sidewalls may be selectively or preferentially etched without feature bottom etching by pre-treatment with a first molybdenum-containing precursor, followed by deposition with a second molybdenum-containing precursor in certain embodiments. An etch of only a feature's sidewalls may also be achieved in certain embodiments by selection of the appropriate molybdenum-containing precursor which has the inherent characteristics favoring feature sidewall etching over feature bottom etching.

In operation 304, part of the metal nitride layer or other conformal liner layer on the sidewalls is etched. This may involve using the precursor used to deposit Mo in operation 304 as an etchant. In some embodiments, the precursor is a molybdenum halide precursor. As discussed above, molybdenum halide precursors may be tuned to be used in both deposition and etch processes.

In some embodiments, a molybdenum halide precursor, such as MoCl₅, can be used to selectively etch the TiN layer from the sidewall surfaces. TiN is generally etched more quickly than the Mo. The TiN layer on the bottom surface of the feature is protected by the Mo deposited in 303.

In some embodiments, operation 304 is performed after operation 303. An example of such an embodiment is discussed further below with respect to FIGS. 4A-4D. In some embodiments, the operations are controlled such that they are performed concurrently or overlap. An example of such an embodiment is discussed further below with respect to FIGS. 5A-5C.

After the Mo film base is deposited, the feature is filled with Mo in an operation 305. The feature may be filled using either a molybdenum halide or a molybdenum oxyhalide precursor. Examples of a molybdenum halide precursor include MoCl₅. As indicated above, examples of MoO_{y}X_{z} precursors include MoO₂Cl₂, MoOCl₄, MoOF₄, MoO₂Br₂, MoO₂I, and Mo₄O₁₁I. The feature may be filled using ALD, plasma enhanced ALD, chemical vapor deposition (CVD), or plasma enhanced CVD. For ALD or CVD, H₂ may be the reducing agent. Mo deposits more quickly using a molybdenum oxyhalide precursor than the MoClₓ precursor used to form the initial Mo layer. For example, a MoO_{y}X_{z} precursor may deposit Mo at a deposition rate at least twice as fast as a MoClₓ precursor for a non-plasma process. Plasma enhanced processes may be used to fill features at lower temperatures and/or increase deposition rates.

Notably, the method may be efficiently operated in a single chamber, simplifying process flow.

FIGS. 4A-4D show schematic examples of the process of FIG. 3. In FIG. 4A, a feature 401 having a conformal TiN liner layer 415 is shown. The feature 401 has a bottom surface 405 and lined feature sidewall surfaces 411. In FIG. 4A, the TiN liner includes the lined feature bottom surface 405 and the sidewall surfaces 411. In some embodiment, the conformal liner layer may be or include a titanium silicon nitride (TiSiₓN). As described above, other liner layers (e.g., WCN) may be employed in place of TiN. In some embodiments, the conformal TiN layer 415 may be oxidized on a top surface of the layer. The feature 401 is formed in a dielectric material 413. An underlying stack 410 is below the feature bottom surface 405. In the example shown, the underlying stack 410 has a metal silicide nitride (MSiₓN_{y}) layer 408 and a metal silicide layer (MSiₓ) 407 connected to a semiconductor layer 406, e.g., silicon (Si) or silicon-germanium (SiGe). This stack 410 may be used in S/D structure. One example of a MSiₓ layer is titanium silicide (TiSiₓ). One example of a metal silicide nitride (MSiₓN_{y}) is a titanium silicide nitride (TiSiₓN_{y}). The conformal TiN liner layer 415 on the bottom surface 405 is used to protect the underlying stack 410 below the feature bottom surface. The TiN liner layer may act as a diffusion barrier, prevent etching of the underlying material, and prevent the underlying material from oxidizing. Other protective layers may be used in alternate embodiments.

The feature 401 may be cleaned as discussed above with reference to operation 302. This may involve flowing a MoClₓ precursor, such as MoCl₅, into the chamber housing the substrate. In some embodiments, the flow of the precursor may be continuous. In still some other embodiments, the flow may be multiple cycles of alternating doses of the MoClₓ precursor and a purge gas. The MoClₓ precursor effectively removes any oxide on the surface. For example, the TiN liner layer 415 may have oxide to form TiOₓN_{y}. The removes the oxide. This may be done without etching any or more than a negligible amount of TiN.

FIG. 4B depicts the feature 401 after a metal film base such as molybdenum film base 409 is deposited in the bottom portion of the feature 401 as described above in operation 303 of FIG. 3. Mo 409 is deposited into the feature by reacting the MoClₓ precursor, such as MoCl₅, and a reactant, such as H₂. For ease of discussion, the description of FIGS. 4A-4D describes MoCl₅ as the MoCl₅ precursor and H₂ as the reactant. However, other molybdenum halides and/or other co-reactants may be employed.

When depositing Mo, the MoCl₅ precursor is flowed into the feature. One or more of partial pressure, reactant flow rate, reactant concentration, and reactant dose time are controlled such that there is a concentration gradient of the MoCl₅ in the feature with higher concentration at the top of the feature and lower concentration at the feature bottom.

At the feature bottom, MoCl₅ reacts with H₂ to form the Mo on the bottom surface 405. The reaction is mass transport limited, allowing deposition without significant etching. Higher in the feature, MoCl₅ also reacts with H₂. However, as there is more MoCl₅ present than at the bottom, the deposited Mo is etched. In some embodiments, no Mo is deposited on the sidewalls. However, in some embodiments, a thin conformal layer is deposited on the sidewalls as shown in FIG. 4B. There is net deposition, but to a much lesser extent than at the feature bottom. This is referred to as selective deposition of Mo at the feature bottom and forms a Mo film base.

In some other embodiments, the H₂ reactant is continuously flowed while the MoCl₅ precursor flow is pulsed. This facilitates selective deposition at the bottom of the feature as depicted in FIG. 4B.

The temperature of the substrate and the pressure of a chamber may be controlled. In some embodiments, the substrate may be heated between 350° C. and 550° C., e.g., between 400° C. and 500° C. In some embodiments, the chamber may be pressurized to at least 10 Torr, e.g., to at least 30 Torr, or to at least 50 Torr.

FIG. 4C depicts the feature 401 after part of the TiN liner layer 415 is etched from the sidewall surfaces 411 as described with reference to operation 305 of FIG. 3. The MoCl₅ precursor is used to etch away the Mo and the TiN liner layer 415 on the sidewall surfaces 411 in an upper portion of the feature 401. The MoCl₅ etches the thin Mo on the sidewall surfaces 411 before etching away the TiN liner layer. In embodiments where no Mo is deposited on the sidewall surface 411, the MoCl₅ etches the TiN liner layer at the top portion of the feature directly The Mo 409 in the bottom portion of the feature 401, due to its thickness, protects the TiN liner layer 415 from being etched away by the MoCl₅ precursor. The TiN liner layer 415 remains at the bottom surface 405 and protects the underlying stack 410 during subsequent processing. As shown, the dielectric material 413 forms the sidewall surfaces 411 after the etch. The remaining TiN layer 415 forms a “cup” around the Mo 409. Together, they protect the underlying stack 410 in subsequent processing and provide a layer on which more Mo can be selectively deposited in a bottom-up process.

FIG. 4D shows the feature 401 after a Mo gap fill of the feature. The feature 401 is filled with a Mo fill 423. The TiN layer 415 remains between the Mo fill 423 and the underlying stack 410 at the bottom of the feature but is not between the Mo fill 423 and the dielectric 413. The feature 401 may be filled using an ALD or a CVD process. The fill may be done with a Mo oxyhalide precursor containing oxygen, a Mo halide precursor not containing oxygen, or a combination thereof. The fill is a bottom-up fill and grows from the Mo film base 409 deposited in the feature bottom. In some embodiments, the fill may be performed in a single stage deposition, where the fill is continued using the same parameters, such as temperature and pressure, as the initial fill. In some other embodiments, the fill may be performed in multi-stage Mo deposition, where parameters may be changed during the deposition. For example, the deposition at a first stage may have a first temperature. After the first stage, the deposition may continue in a second stage and may have a second temperature higher than the first temperature. The increase in temperature may be used to increase the rate of Mo bulk fill, decreasing processing time. In another example of multi-stage deposition, the Mo precursor and reactant concentrations may be varied at different stages. For example, a Mo halide precursor may start the Mo fill, followed by a Mo oxyhalide precursor. The Mo oxyhalide precursor may be used to increase processing speed.

FIGS. 5A-5C show a second schematic example of the process of FIG. 3. FIG. 5A shows the feature 501 with a TiN liner layer 515 that forms a bottom surface 505 and sidewall surfaces 511. In FIG. 5A, the TiN liner includes the lined feature bottom surface 505 and the lined feature sidewall surfaces 511. In some embodiments, the TiN layer 515 may be oxidized on a top surface of the layer. The feature 501 is formed in a dielectric material 513. An underlying stack 510 is below the feature bottom surface 505. The underlying stack 510 is similar to the underlying stack 410 described above in FIG. 4A. In the example shown, the underlying stack 510 has a metal silicide nitride (MSiₓN_{y}) layer 508 and a metal silicide layer (MSiₓ) 507 connected to a semiconductor layer 506, e.g., silicon (Si) or silicon-germanium (SiGe). The feature 501 may be cleaned as discussed in operation 302. The clean may be used to remove any oxide on the surfaces of the feature 501.

FIG. 5B shows the feature 501 after operations 303 and 304 of FIG. 3 are performed in the same operation. A metal film base such as a molybdenum film base 509 is deposited while the TiN liner layer 515 is etched from the sidewall surfaces 511. The Mo film base 509 is deposited on the bottom surface 505 of the feature 501 and grows upward from there. In some embodiments, multiple cycles of alternating pulses of molybdenum halide precursor and reactant is used to deposit Mo film base 509 and etch TiN liner layer. For example, MoCl₅ may be flowed without H₂. The MoCl₅ has a concentration gradient with higher amounts of MoCl₅ toward the top of the feature than the bottom. The MoCl₅ will etch at the top of the feature, i.e., the sidewall surfaces 511, while the lower concentration of MoCl₅ will remain in the feature. The MoCl₅ flow is stopped. The reactant, e.g., H₂ for example, is then flowed. The remaining MoCl₅ in the feature reacts with H₂ and deposits Mo film base 509 at the feature bottom. This process is cycled, removing more and more of the TiN liner layer 515 on the sidewall surfaces and depositing additional Mo film base 509 after each cycle. In some embodiments, each cycle ends with a purge. For example, one of the following sequences may be cycled:
molybdenum halide precursor/reducing agent
molybdenum halide precursor/reducing agent/purge

Notably, there is no purge between the molybdenum halide precursor and reducing agent to allow the two reactants to react. If a purge is used, it is generally incomplete to allow molybdenum halide precursor to remain in the feature available to react. In some embodiments, the MoCl₅ may be continuous while the H₂ reactant is pulsed.

After the end of this process, the TiN liner layer is etched away from at least a top portion of the feature such that the sidewall surfaces 511 in the top portion are the dielectric material 513 and Mo film base 509 is formed on the TiN liner layer on the bottom surface 505. The TiN liner layer 515 remains on the bottom of the feature 501 and protects the underlying stack 510.

As discussed above in operation 303 of FIG. 3, the temperature of the substrate and the pressure of a chamber may be controlled. In some embodiments, the substrate may be heated between 350° C. and 550° C., e.g., between 400° C. and 500° C. In some embodiments, the chamber may be pressurized to at least 10 Torr, e.g., to at least 30 Torr, or to at least 50 Torr. In some embodiments, process parameters such as temperature and pressure, may be used to control selectivity.

FIG. 5C shows the feature 501 after a Mo gap fill of the feature. The feature 501 is filled with a Mo fill 523. The feature may be filled using a CVD or ALD process. The fill is a bottom-up fill and grows from the initial Mo film base 509 deposited in the feature bottom. The fill is similar to the fill described in 4D. The TiN layer 515 remains between the Mo fill 523 and the underlying stack 510.

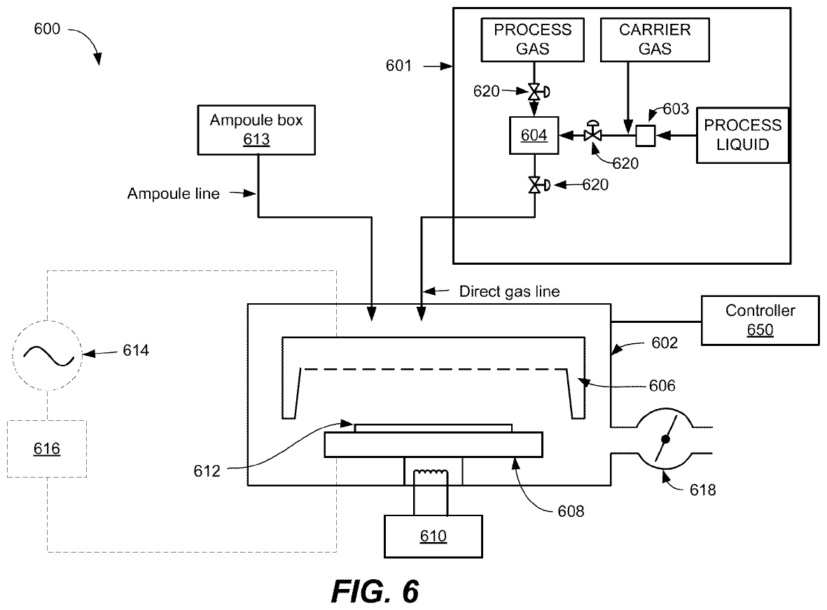

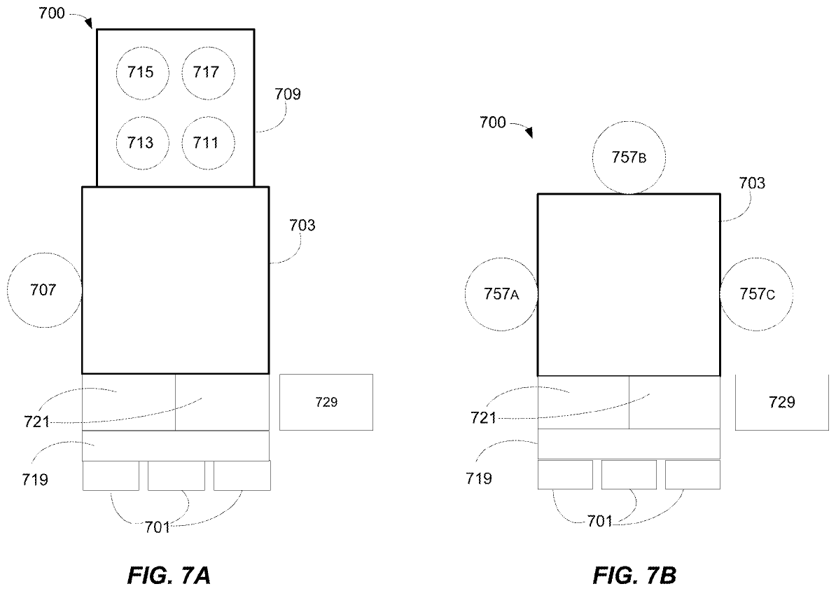

FIG. 6 depicts a schematic illustration of an embodiment of a process station 600 having a process chamber 602 for maintaining a low-pressure environment. In some embodiments, a plurality of process stations may be included in a common low-pressure process tool environment. For example, FIG. 7A depicts an embodiment of a multi-station processing tool 700. In some embodiments, one or more hardware parameters of process station 600, including those discussed in detail below, may be adjusted programmatically by one or more computer controllers 650. In some other embodiments, a process chamber may be a single station chamber.

Process station 600 fluidly communicates with reactant delivery system 601 for delivering process gases to a distribution showerhead 606. Reactant delivery system 601 includes a mixing vessel 604 for blending and/or conditioning process gases, such as a Mo precursor-containing gas, a hydrogen-containing gas, an argon or other carrier gas, or other reactant-containing gas, for delivery to showerhead 606. One or more mixing vessel inlet valves 620 may control introduction of process gases to mixing vessel 604. In various embodiments, deposition of an initial Mo layer is performed in process station 600 and in some embodiments, other operations such as in-situ clean or Mo gap fill may be performed in the same or another station of the multi-station processing tool 600 as further described below with respect to FIG. 7.

As an example, the embodiment of FIG. 6 includes a vaporization point 603 for vaporizing liquid reactant to be supplied to the mixing vessel 604. In some embodiments, vaporization point 603 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 604. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller (LFC) upstream of vaporization point 603 may be provided for controlling a mass flow of liquid for vaporization and delivery to process chamber 602. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 606 distributes process gases toward substrate 612. In the embodiment shown in FIG. 6, the substrate 612 is located beneath showerhead 606 and is shown resting on a pedestal 608. Showerhead 606 may have any suitable shape and may have any suitable number and arrangement of ports for distributing process gases to substrate 612.

In some embodiments, pedestal 608 may be raised or lowered to expose substrate 612 to a volume between the substrate 612 and the showerhead 606. In some embodiments, pedestal 608 may be temperature controlled via heater 610. Pedestal 608 may be set to any suitable temperature, such as between about 300° C. and about 500° C. during operations for performing various disclosed embodiments. It will be appreciated that, in some embodiments, pedestal height may be adjusted programmatically by a suitable computer controller 650. At the conclusion of a process phase, pedestal 608 may be lowered during another substrate transfer phase to allow removal of substrate 612 from pedestal 608.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers 650. The computer controller 650 may include any of the features described below with respect to controller 650 of FIG. 6.

In some embodiments where plasma may be used as discussed above, showerhead 606 and pedestal 608 electrically communicate with a radio frequency (RF) power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a Mo precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as H₂, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to the process station 600.

FIGS. 7A and 7B show examples of processing systems. FIG. 7A shows an example of a processing system including multiple chambers. The system 700 includes a transfer module 703. The transfer module 703 provides a clean, vacuum environment to minimize risk of contamination of substrates being processed as they are moved between various modules. Mounted on the transfer module 703 is a multi-station chamber 709 capable of performing in-situ clean and/or ALD processes described above. Initial Mo layer deposition may be performed in the same or different station or chamber as the subsequent Mo gap fill.

Chamber 709 may include multiple stations 711, 713, 715, and 717 that may sequentially perform operations in accordance with disclosed embodiments. For example, chamber 709 may be configured such that station 711 performs an in-situ clean of the substrate using a MoClₓ precursor, as described in FIG. 3, stations 713, 715, 717 performs deposition of the initial Mo layer using the MoClₓ precursor and H₂, with the station 711 also performing etch of the TiN layer. In another example, chamber 709 may be configured such that station 711 performs in-situ clean, station 713 performs deposition of an initial Mo layer and concurrent etch of a nitride liner layer, and stations 713 and 714 deposition of bulk Mo by ALD or CVD. In another example, the chamber 709 may be configured to do parallel processing of substrates, with each station performing multiple processes sequentially.

Two or more stations may be included in a multi-station chamber, e.g., 2-6, with the operations appropriately distributed. For example, a two-station chamber may be configured to perform deposition of an initial Mo layer and etch of a nitride layer in a first station followed by ALD of bulk Mo in a second station. Stations may include a heated pedestal or substrate support, one or more gas inlets or showerhead or dispersion plate.

Also mounted on the transfer module 703 may be one or more single or multi-station modules 707. In some embodiments, a preclean as described above may be performed in a module 707, after which the substrate is transferred under vacuum to another module (e.g., another module 707 or chamber 709) for deposition.

The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In some embodiments, deposition of Mo is performed in a first chamber, which may be part of a system like system 700, with CVD or PVD of W or Mo or other conductive material deposited as an overburden layer performed in another chamber, which may not be coupled to a common transfer module, but part of another system.

FIG. 7B is an embodiment of a system 700, as described in FIG. 7A. The system 700 in FIG. 7B has wafer source modules 701, a transfer module 703, atmospheric transfer chamber 719, and loadlocks 721, as described above with reference to FIG. 7A. The system in FIG. 7B has three single station modules 757. The system 700 may be configured to sequentially perform operations in accordance with disclosed embodiments. For example, the single station modules 757 may be configured so that a first module 757a performs a cleaning operation, a second module 757b performs ALD of an initial Mo layer using a MoClₓ precursor, and a third module 757c performs ALD of bulk Mo using a molybdenum oxyhalide precursor. In this example, an in-situ clean may be optionally performed in second module 757b instead of or in addition to a preclean in first module 757a. Stations may include a heated pedestal or substrate support, one or more gas inlets or showerhead or dispersion plate as described above with reference to FIG. 6.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all the activities of the apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically, there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the Mo precursor pulses, hydrogen pulses, and argon flow, and other processes in a process sequence can be written in any conventional computer readable programming language: for example, assembly language, C, C++. Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 729. The signals for controlling the process are output on the analog and digital output connections of the deposition apparatus.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 729, in some implementations, may be a part of or coupled to a computer that is integrated with, coupled to the system, otherwise networked to the system, or a combination thereof. For example, the controller 729 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 729 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Although the foregoing embodiments have been described in some detail for purposes of clarity of understanding, it will be apparent that certain changes and modifications may be practiced within the scope of the appended claims. It should be noted that there are many alterative ways of implementing the processes, systems and apparatus of the present embodiments. Accordingly, the present embodiments are to be considered as illustrative and not restrictive, and the embodiments are not to be limited to the details given herein.

1. A method for filling a feature, the method comprising:
providing a substrate comprising a feature having a feature bottom and feature sidewalls in a deposition chamber, the feature having a conformal liner layer comprising a lined feature bottom surface and lined feature sidewall surfaces;
selectively depositing a metal film on the lined feature bottom surface using a metal precursor and a reducing agent to form a metal film base;
preferentially etching the conformal liner layer from the feature sidewalls over etching the metal film base with the metal precursor; and
using the metal precursor, depositing metal in the feature on the metal film base.

2. The method of claim 1, wherein the reducing agent comprises hydrogen, hydrazine, ammonia, silane, disilane, diborane, or a combination thereof.

3. The method of claim 1, wherein the conformal liner layer comprises titanium nitride, titanium silicide nitride, tungsten carbon nitride, or a combination thereof.

4. The method of claim 1, wherein the metal precursor comprises a molybdenum halide, a molybdenum oxyhalide or a combination thereof

5. The method of claim 1, wherein forming the metal film base and etching the conformal liner layer from the feature sidewalls occur sequentially.

6. The method of claim 1, wherein forming the metal film base and etching the conformal liner layer from the feature sidewalls occur simultaneously.

7. The method of claim 4, wherein the molybdenum halide comprises molybdenum dichloride, molybdenum trichloride, molybdenum tetrachloride, molybdenum pentachloride, molybdenum hexachloride, or molybdenum fluoride.

8. The method of claim 4, wherein the molybdenum oxyhalide comprises molybdenum dichloride dioxide, molybdenum tetrachloride oxide, molybdenum tetrafluoride oxide, or molybdenum dibromide dioxide.

9. The method of claim 1, wherein a temperature of the substrate during deposition is from about 350° C. to about 550° C.

10. The method of claim 1, wherein a pressure in the deposition chamber is from about 10 Torr to about 50 Torr.

11. The method of claim 1, wherein depositing comprises filling the feature with metal.

12. The method of claim 11, wherein the substrate further comprises a top surface, and wherein the top surface is coated with titanium disilicide.

13. The method of claim 1, further comprising pre-treating the conformal liner layer to clean it prior to deposition of the metal film.

14. The method of claim 1, wherein preferentially etching comprises etching the conformal liner layer from the feature sidewalls without etching the metal film base.

15. A method for filling a feature, the method comprising:
providing a substrate comprising a feature having a feature bottom and feature sidewalls in a deposition chamber, the feature having a conformal liner layer comprising a lined feature bottom surface and lined feature sidewall surfaces;
selectively depositing a molybdenum film on the lined feature bottom surface with a molybdenum precursor and a reducing agent to form a molybdenum film base;
preferentially etching the conformal liner layer with the molybdenum precursor to remove the lined feature sidewall surfaces over etching the molybdenum film base; and
depositing molybdenum in the feature on the molybdenum film base with the molybdenum precursor.

16. The method of claim 15, wherein the molybdenum precursor comprises a molybdenum halide or a molybdenum oxyhalide.

17. The method of claim 16, wherein the molybdenum oxyhalide comprises molybdenum dichloride dioxide, molybdenum tetrachloride oxide, molybdenum tetrafluoride oxide, or molybdenum dibromide dioxide.

18. The method of claim 16, wherein the molybdenum halide comprises molybdenum dichloride, molybdenum trichloride, molybdenum tetrachloride, molybdenum pentachloride, molybdenum hexachloride, or molybdenum fluoride.

19. The method of claim 18, wherein the molybdenum halide comprises molybdenum pentachloride.

20. The method of claim 15, wherein preferentially etching comprises etching the conformal liner layer from the feature sidewalls without etching the molybdenum film base.

21. A method for filling a feature, the method comprising:
providing a substrate comprising a feature having a feature bottom and feature sidewalls in a deposition chamber, the feature having a conformal liner layer comprising a lined feature bottom surface and lined feature sidewall surfaces;
selectively depositing a molybdenum film on the lined feature bottom surface with a first molybdenum precursor and a reducing agent to form a molybdenum film base;
preferentially etching the conformal liner layer with a second molybdenum precursor to remove the lined feature sidewall surfaces over etching the molybdenum film base; and
depositing molybdenum in the feature on the molybdenum film base with the first molybdenum precursor.

22. The method of claim 21, wherein preferentially etching comprises etching the conformal liner layer from the feature sidewalls without etching the molybdenum film base.

23. An apparatus for filling a feature on a substrate, the apparatus comprising:
at least one deposition chamber including a pedestal for holding a substrate comprising a feature having a feature bottom and feature sidewalls, the feature having a conformal liner layer comprising a lined feature bottom surface and lined feature sidewall surfaces;
at least one inlet port for delivering gas phase metal precursors to the deposition chamber;
and
a controller for controlling operations in the apparatus, including machine-readable instructions for:
(a) causing deposition of a molybdenum film on the lined feature bottom surface with a molybdenum precursor and a reducing agent;
(b) preferentially etching the conformal liner layer with the molybdenum precursor to remove the lined feature sidewall surfaces over etching the lined feature bottom surface; and
(c) after (b), depositing molybdenum in the feature with the molybdenum precursor.
